(19) United States
(12) Patent Application Publication
(10) Pub. No.: US 2006/0081858 A1
(43) Pub. Date: Apr. 20, 2006

(54) Light emitting device with omnidirectional reflectors

(76) Inventors: Chung-Hsiang Lin, Taipei City (TW); Chang-Chin Yu, Hsin-Tien City (TW); Jun-Ren Lo, Pan-Chiao City (TW)

Correspondence Address: Allston L. Jones;PETERS, VERNY, JONES & SCHMITT LLP, Suite 230, 425 Sherman Avenue, Palo Alto, CA, 94306-1840, US

(21) Appl. No.: 10/965,579

(22) Filed: Oct. 14, 2004

(51) Int. Cl. H01L 33/00

(52) U.S. Cl. 257/85

(57) ABSTRACT

A light emitting device includes a semiconductor structure having lateral side faces, and including a light-generating layer, and two omnidirectional reflectors disposed respectively at two sides of the light-generating layer. Each of the omnidirectional reflectors exhibits a periodic variation indielectric constant in such a manner so as to introduce an omnidirectional photonic band gap in a given frequency range such that the radiation generated by the light-generating layer in the frequency range for all incident angles and polarizations can be totally reflected by the omnidirectional reflectors and can be extracted substantially only from the lateral side faces of the semiconductor structure.

### BACKGROUND OF THE INVENTION

1. Field of the Invention

This invention relates to a light emitting device including a semiconductor structure with two omnidirectional reflectors formed respectively on top and bottom sides of the semiconductor structure.

2. Description of the Related Art

FIG. 1 illustrates a conventional LED light source unit 10 for an LCD backlighting moduleing module (not shown). The light source unit 10 provides light to an LCD panel through a reflector for displaying an image on the LCD panel. The light source unit 10 includes a casing 103, a light source 101 having an array of light emitting diodes (LED) 104 mounted in the casing 103, and a light guiding plate 102 for guiding light generated by the light source 101.

Since each of the LEDs 104 emits light through an upper surface of the LED 104, which has relatively large dimensions (about 300 μm×300 μm), the thickness (h) of the casing 103 is relatively thick, which has an adverse effect on minimization of the thickness of the light guiding plate 102.

U.S. Patent Application Publication No. US 2002/0121643 discloses a surface-light-emitting device that includes a semiconductor structure having a light-generating layer interposed between upper and lower multi-film reflectors (e.g., Distributed Bragg Reflector, DBR) which constitute a light resonator that permits the light-generating layer to generate light only in a resonance mode and that provides a cavity quantum electrodynamics (QED) effect, which permits the light generated by the light-generating layer to have a high degree of directivity and a narrow line width, and which prevents total reflection of the light by the crystal surface of the DBR so as to assure an advantage of a high degree of external quantum efficiency. The light generated by the light-generating layer is emitted from a light-emitting surface of the semiconductor structure on which a p-side electrode is formed.

In practice, the lower DBR has a higher reflectivity than that of the upper DBR so as to permit emission of the light from the light-generating surface of the semiconductor structure.

U.S. Pat. No. 6,130,780 discloses a highly omnidirectional reflector that includes a periodic photonic structure with a surface and a refractive index variation along a direction perpendicular to the surface and that exhibits complete reflection of radiation in a given frequency range for all incident angles and polarizations.

The entire disclosures of U.S. Patent Application Publication No. US 2002/0121643 and U.S. Pat. No. 6,130,780 are incorporated herein by reference.

### SUMMARY OF THE INVENTION

The object of the present invention is to provide a light emitting device with two omnidirectional reflectors that permit emission of light generated by a light-generating layer of the light emitting device from at least one of lateral side faces of the light emitting device so that the dimensions of the casing of the light emitting device can be reduced and so that the extraction efficiency of the light emitting device can be enhanced.

According to the present invention, there is provided a light emitting device that comprises: a laminar semiconductor structure having a bottom face, a top face opposite to the bottom face, and lateral side faces extending from the top face to the bottom face, and including a light-generating layer that has opposite top and bottom sides, and opposite upper and lower omnidirectional reflectors disposed respectively at the top and bottom sides of the light-generating layer. Each of the upper and lower omnidirectional reflectors exhibits a periodic variation in dielectric constant in such a manner so as to introduce an omnidirectional photonic band gap in a given frequency range such that the radiation generated by the light-generating layer in the frequency range for all incident angles and polarizations can be totally reflected by the upper and lower omnidirectional reflectors and can be extracted substantially only from the lateral side faces of the semiconductor structure.

### BRIEF DESCRIPTION OF THE DRAWINGS

In drawings which illustrate embodiments of the invention,

FIG. 1 is a schematic perspective view of a conventional light source unit for an LCD backlighting module;

FIG. 2 is a schematic view of the first preferred embodiment of a light emitting device according to this invention;

FIG. 3 is a schematic view of the second preferred embodiment of the light emitting device according to this invention;

FIG. 4 is a schematic perspective view of the third preferred embodiment of the light emitting device according to this invention;

FIG. 5 is a schematic view of the third preferred embodiment of the light emitting device according to this invention;

FIG. 6 is a schematic perspective view of the fourth preferred embodiment of the light emitting device according to this invention;

FIG. 7 is a fragmentary, schematic view of an omnidirectional reflector for each of the preferred embodiments;

FIG. 8 is a schematic view of the preferred embodiment of a light source unit for an LCD backlighting module according to this invention; and

FIG. 9 is a schematic view of the fifth preferred embodiment of the light source unit according to this invention.

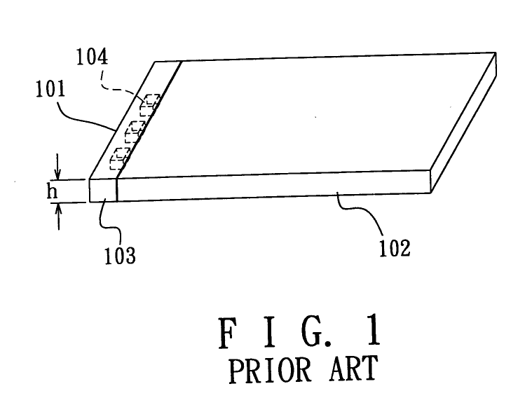

### DETAILED DESCRIPTION OF THE PREFERRED EMBODIMENTS

For the sake of brevity, like elements are denoted by the same reference numerals throughout the disclosure.

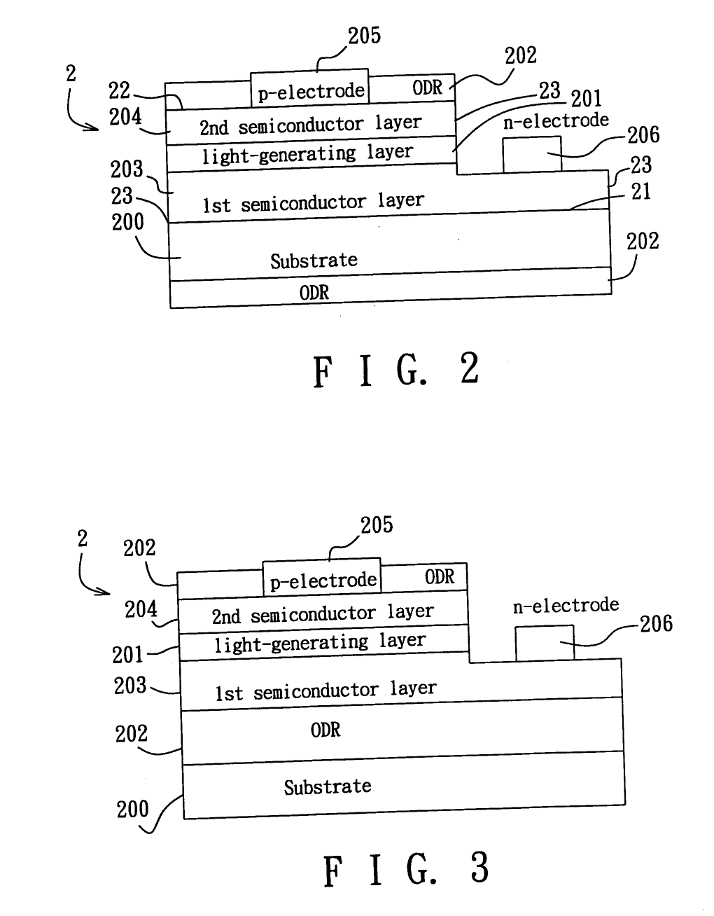

FIG. 2 illustrates the first preferred embodiment of a light emitting device according to the present invention.

The light emitting device includes: a laminar semiconductor structure 2 having a bottom face 21, atop face 22 opposite to the bottomface 21, and lateral side faces 23 extending from the top face 22 to the bottom face 21, and including a light-generating layer 201 that has opposite top and bottom sides, and opposite upper and lower omnidirectional reflectors (ODR) 202 disposed respectively at the top and bottom sides of the light-generating layer 201. Each of the upper and lower omnidirectional reflectors 202 exhibits a periodic variation in dielectric constant in such a manner so as to introduce an omnidirectional photonic band gap in a given frequency range such that the radiation generated by the light-generating layer 201 in the frequency range for all incident angles and polarizations can be totally reflected by the omnidirectional reflectors 202 and can be extracted substantially only from the lateral side faces 23 of the semiconductor structure 2.

In this embodiment, the semiconductor structure 2 further includes a substrate 200 formed on the lower omnidirectional reflector 202, a first semiconductor layer 203 formed on and sandwiched between the light-generating layer 201 and the substrate 200, and a second semiconductor layer 204 opposite to the first semiconductor layer 203 and formed on and sandwiched between the light-generating layer 201 and the upper omnidirectional reflector 202.

FIG. 3 illustrates the second preferred embodiment of the light emitting device according to the present invention. The light emitting device of this embodiment differs from the previous embodiment in that the semiconductor structure 2 includes opposite first and second semiconductor layers 203, 204 that sandwich the light-generating layer 201 therebetween. The first semiconductor layer 203 is formed on and is sandwiched between the lower omnidirectional reflector 202 and the light-generating layer 201. The second semiconductor layer 204 is formed on and is sandwiched between the light-generating layer 201 and the upper ominidirectional reflector 202. The substrate 200 is formed on the lower omnidirectional reflector 202 and is opposite to the first semiconductor layer 203.

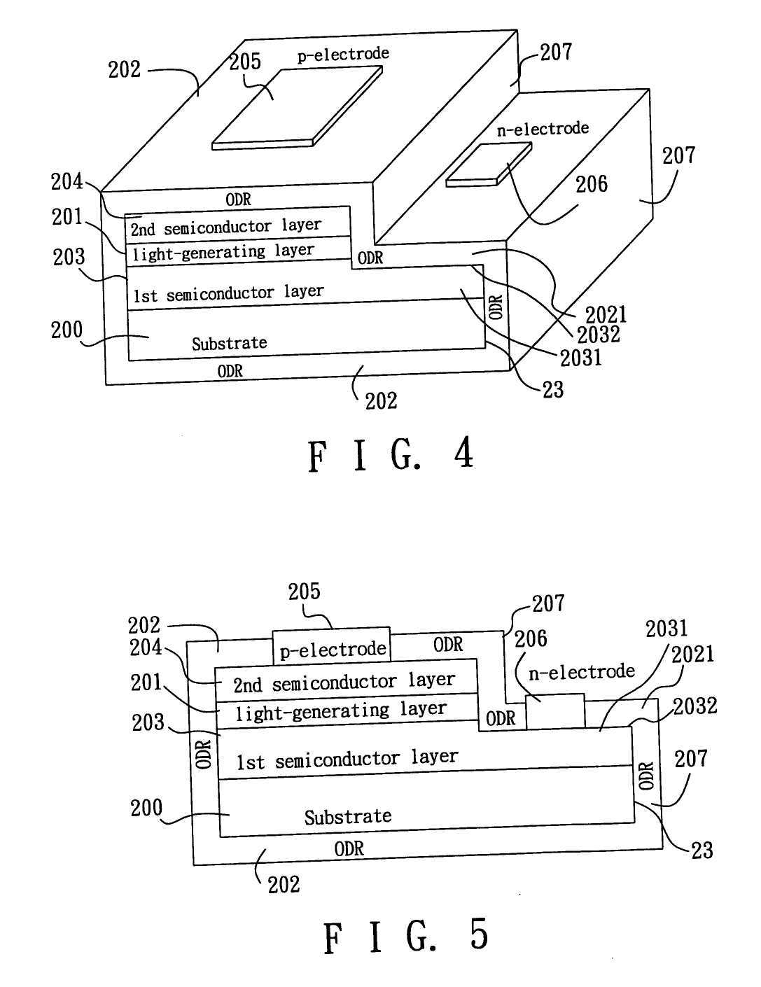

FIGS. 4 and 5 illustrate the third preferred embodiment of the light emitting device according to the present invention. The light emitting device of this embodiment differs from the previous embodiment in that the first semiconductor layer 203 has a lateral portion 2031 extending laterally beyond the light-generating layer 201 and the second semiconductor layer 204, and an upper face 2032 that is exposed from the light-generating layer 201 and the second semiconductor layer 204. The semiconductor structure 2 further includes a p-electrode 205 that is formed on the second semiconductor layer 204, an n-electrode 206 that is formed on the upper face 2032 of the first semiconductor layer 203, and side ominidirectional reflectors 207 that are respectively formed on all except one of the lateral side faces 23. The upper omnidirectional reflector 202 has a portion 2021 that is formed on the upper face 2032 of the first semiconductor layer 203. The upper and lower ODRs 202 and the side ODRs 207 permit the radiation generated by the light-generating layer 201 in the frequency range to be extracted substantially only from said one of the lateral side faces 23 of the semiconductor structure 2.

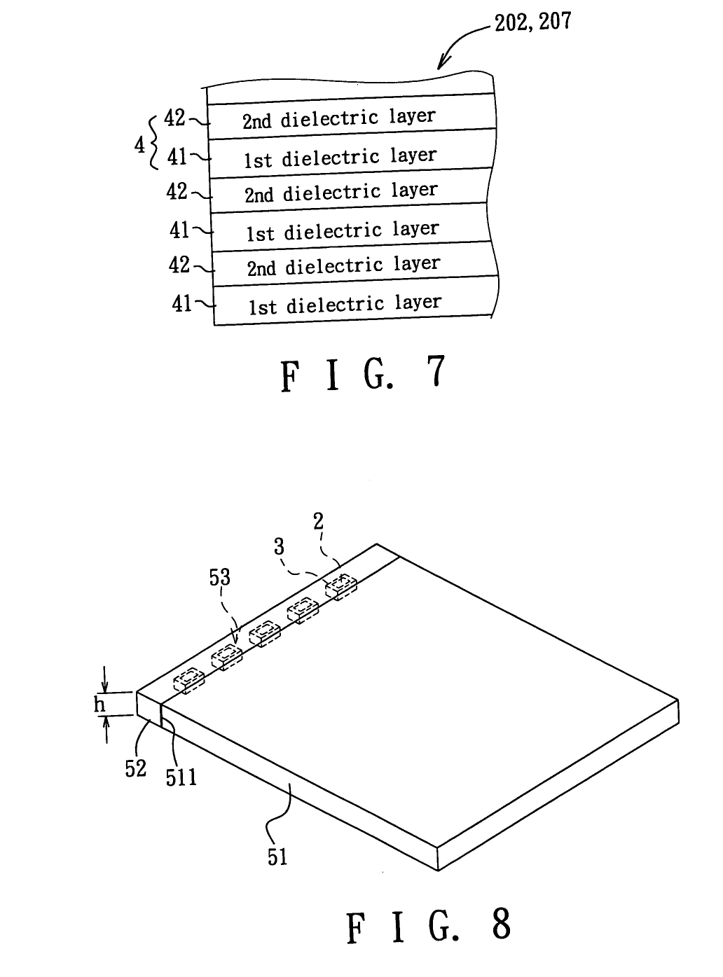

As best shown in FIG. 7, each of the upper and lower ODRs 202 and the side ODRs 207 is a photonic crystal that includes periodically stacked units 4, each of which includes at least first and second dielectric layers 41, 42 that differ in dielectric constant.

Preferably, the first dielectric layer 41 is made from a material selected from the group consisting of TiO₂, Ta₂O₅, ZrO₂, ZnO, Nd₂O₃, Nb₂O₅, In₂O₃, SnO₂, Sb₂O₃, HfO₂, CeO₂, and ZnS. The second dielectric layer 42 is made from a material selected from the group consisting of SiO₂, Al₂O₃, MgO, La₂O₃, Yb₂O₃, Y₂O₃, Sc₂O₃, WO₃, LiF, NaF, MgF₂, CaF₂, SrF₂, BaF₂, AlF₃, LaF₃, NdF₃, YF₃, and CeF₃. More preferably, the first dielectric layer 41 is made from TiO₂, and the second dielectric layer 42 is made from SiO₂.

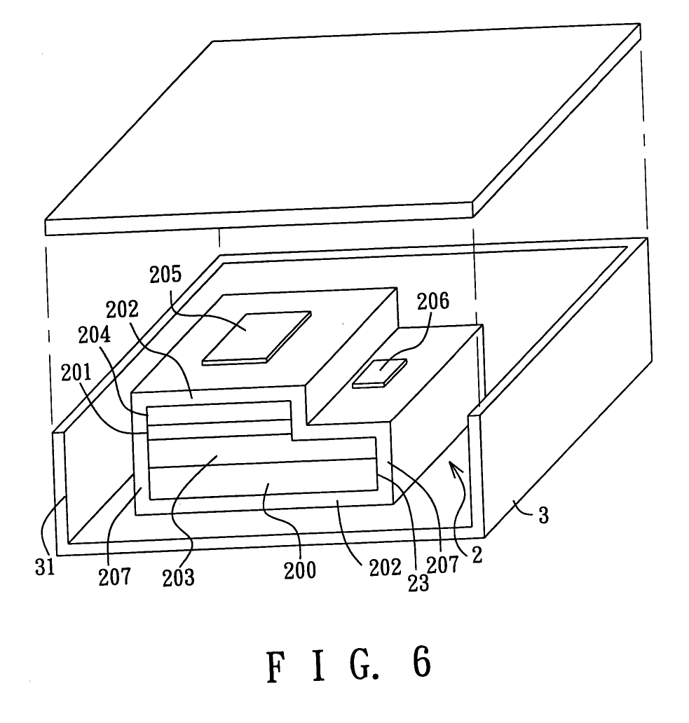

FIG. 6 illustrates the fourth preferred embodiment of the light emitting device according to the present invention. The light emitting device of this embodiment differs from the third embodiment in that a housing 3 is provided to accommodate the semiconductor structure 2. The semiconductor structure 2 is mounted in the housing 3 in such a manner that said one of the lateral sides 23 of the semiconductor structure 2 confronts an open side 31 of the housing 3 so as to permit emission of the radiation generated by the light-generating layer 201 in the frequency range through the open side 31 of the housing 3.

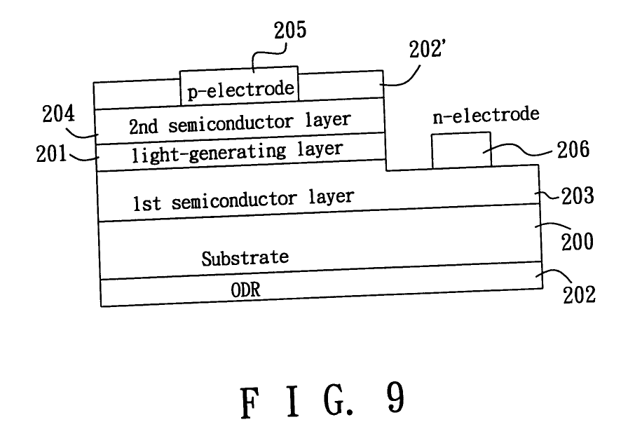

FIG. 8 illustrates the preferred embodiment of a light source unit 5 for an LCD backlighting module (not shown) according to this invention. The light source unit 5 includes a flat light-guiding plate 51 having a light-mounting side 511, a casing 52 mounted on the light-mounting side 511 of the light-guiding plate 51, and a light source 53 including an array of the light emitting devices of FIG. 6 that are mounted in the casing 52.

FIG. 9 illustrates the fifth preferred embodiment of the light emitting device according to the present invention. The light emitting device of this embodiment differs from the first embodiment in that the upper omnidirectional reflector 202 shown in FIG. 2 is replaced by a metal reflecting layer 202′ that is made from metal. The metal reflecting layer 202′ cooperates with the omnidirectional reflector 202 to enable the radiation generated by the light-generating layer 201 to be extracted substantially only from the lateral side faces of the semiconductor structure.

Since the radiation generated by the light generating layer 201 is emitted from said at least one of the lateral sides 23, which has small dimensions (about 100 μm×300 μm), by virtue of the upper and lower ODRs 202 or the metal reflecting layer 202′ and the lower ODR 202 in the light emitting device of this invention, the thickness (h) of the casing 52 can be reduced as compared to that of the aforesaid conventional surface-light-generating device, thereby permitting a corresponding reduction in the thickness of the light-guiding plate 51. Moreover, by virtue of the upper and lower ODRs 202, the extraction efficiency of each light emitting device of this invention can be enhanced.

With the invention thus explained, it is apparent that various modifications and variations can be made without departing from the spirit of the present invention.

I claim:

1. A light emitting device comprising:
a laminar semiconductor structure having a bottom face, a top face opposite to said bottom face, and lateral side faces extending from said top face to said bottom face, and including a light-generating layer that has opposite top and bottom sides, and opposite upper and lower omnidirectional reflectors disposed respectively at said top and bottom sides of said light-generating layer;
wherein each of said upper and lower omnidirectional reflectors exhibits a periodic variation in dielectric constant in such a manner so as to introduce an omnidirectional photonic band gap in a given frequency range such that the radiation generated by said light-generating layer in said frequency range for all incident angles and polarizations can be totally reflected by said upper and lower omnidirectional reflectors and can be extracted substantially only from said lateral side faces of said semiconductor structure.

2. The light emitting device of claim 1, wherein said semiconductor structure further includes a substrate formed on said lower omnidirectional reflector, a first semiconductor layer formed on and sandwiched between said light-generating layer and said substrate, and a second semiconductor layer opposite to said first semiconductor layer and formed on and sandwiched between said light-generating layer and said upper omnidirectional reflector.

3. The light emitting device of claim 1, wherein said semiconductor structure further includes opposite first and second semiconductor layers that sandwich said light-generating layer therebetween, said first semiconductor layer being formed on and being sandwiched between said lower omnidirectional reflector and said light-generating layer, said second semiconductor layer being formed on and being sandwiched between said light-generating layer and said upper ominidirectional reflector.

4. The light emitting device of claim 3, further comprising a substrate that is formed on said lower omnidirectional reflector and that is opposite to said first semiconductor layer.

5. The light emitting device of claim 2, wherein said first semiconductor layer has a lateral portion extending laterally beyond said light-generating layer and said second semiconductor layer, and an upper face that is exposed from said light-generating layer and said second semiconductor layer, said semiconductor structure further including a p-electrode that is formed on said second semiconductor layer, an n-electrode that is formed on said upper face of said first semiconductor layer, and side ominidirectional reflectors that are respectively formed on all except one of said lateral side faces, said upper omnidirectional reflector having a portion that is formed on said upper face of said first semiconductor layer.

6. The light emitting device of claim 5, further comprising a housing having an open side, said semiconductor structure being mounted in said housing in such a manner that said one of said lateral sides of said semiconductor structure confronts said open side of said housing so as to permit emission of the radiation generated by said light-generating layer in said frequency range through said open side of said housing.

7. The light emitting device of claim 5, wherein each of said upper and lower omnidirectional reflectors and said side omnidirectional reflectors is a photonic crystal that includes periodically stacked units, each of which includes at least first and second dielectric layers that differ in dielectric constant.

8. The light emitting device of claim 7, wherein said first dielectric layer is made from a material selected from the group consisting of TiO₂, Ta₂O₅, ZrO₂, ZnO, Nd₂O₃, Nb₂O₅, In₂O₃, SnO₂, Sb₂O₃, HfO₂, CeO₂, and ZnS, and said second dielectric layer is made from a material selected from the group consisting of SiO₂, Al₂O₃, MgO, La₂O₃, Yb₂O₃, Y₂O₃, Sc₂O₃, WO₃, LiF, NaF, MgF₂, CaF₂, SrF₂, BaF₂, AlF₃, LaF₃, NdF₃, YF₃, and CeF₃.

9. A light emitting device comprising:
a laminar semiconductor structure having a bottom face, a top face opposite to said bottom face, and lateral side faces extending from said top face to said bottom face, and including a light-generating layer that has opposite top and bottom sides, a metal reflecting layer disposed at said top side of said light-generating layer, and an omnidirectional reflector disposed at said bottom side of said light-generating layer;
wherein said omnidirectional reflector exhibits a periodic variation in dielectric constant in such a manner so as to introduce an omnidirectional photonic band gap in a given frequency range such that the radiation generated by said light-generating layer in said frequency range for all incident angles and polarizations can be totally reflected by said omnidirectional reflector; and
wherein said metal reflecting layer cooperates with said omnidirectional reflector to enable the radiation generated by said light-generating layer to be extracted substantially only from said lateral side faces of said semiconductor structure.

10. The light emitting device of claim 9, wherein said semiconductor structure further includes a substrate formed on said lower omnidirectional reflector, a first semiconductor layer formed on and sandwiched between said light-generating layer and said substrate, and a second semiconductor layer opposite to said first semiconductor layer and formed on and sandwiched between said light-generating layer and said metal reflecting layer.

11. The light emitting device of claim 10, wherein said first semiconductor layer has a lateral portion extending laterally beyond said light-generating layer and said second semiconductor layer, and an upper face that is exposed from said light-generating layer and said second semiconductor layer, said semiconductor structure further including a p-electrode that is formed on said second semiconductor layer, an n-electrode that is formed on said upper face of said first semiconductor layer.

12. The light emitting device of claim 11, wherein said lower omnidirectional reflector is a photonic crystal that includes periodically stacked units, each of which includes at least first and second dielectric layers that differ in dielectric constant.

13. The light emitting device of claim 12, wherein said first dielectric layer is made from a material selected from the group consisting of TiO₂, Ta₂O₅, ZrO₂, ZnO, Nd₂O₃, Nb₂O₅, In₂O₃, SnO₂, Sb₂O₃, HfO₂, CeO₂, and ZnS, and said second dielectric layer is made from a material selected from the group consisting of SiO₂, Al₂O₃, MgO, La₂O₃, Yb₂O₃, Y₂O₃, Sc₂O₃, WO₃, LiF, NaF, MgF₂, CaF₂, SrF₂, BaF₂, AlF₃, LaF₃, NdF₃, YF₃, and CeF₃.

14. A light source unit for a backlight, comprising:
a flat light-guiding plate having a light-mounting side;
a casing mounted on said light-mounting side of said light-guiding plate; and
a light source including a casing and an array of light emitting devices that are mounted in said casing, each of said light emitting devices including
a laminar semiconductor structure having a bottom face, a top face opposite to said bottom face, and lateral side faces extending from said top face to said bottom face, and including a light-generating layer that has opposite top and bottom sides, and upper and lower omnidirectional reflectors disposed respectively at said top and bottom sides of said light-generating layer;
wherein each of said upper and lower omnidirectional reflectors exhibits a periodic variation in dielectric constant in such a manner so as to introduce an omnidirectional photonic band gap in a given frequency range such that the radiation generated by said light-generating layer in said frequency range for all incident angles and polarizations can be totally reflected by said upper and lower omnidirectional reflectors and can be extracted substantially only from said lateral side faces of said semiconductor structure.

15. The light source unit of claim 14, wherein said semiconductor structure further includes a substrate formed on said lower omnidirectional reflector, a first semiconductor layer formed on and sandwiched between said light-generating layer and said substrate, and a second semiconductor layer opposite to said first semiconductor layer and formed on and sandwiched between said light-generating layer and said upper omnidirectional reflector.

16. The light source unit of claim 14, wherein said semiconductor structure further includes opposite first and second semiconductor layers that sandwich said light-generating layer therebetween, said first semiconductor layer being formed on and being sandwiched between said lower omnidirectional reflector and said light-generating layer, said second semiconductor layer being formed on and being sandwiched between said light-generating layer and said upper ominidirectional reflector.

17. The light source unit of claim 16, wherein said semiconductor structure further includes a substrate that is formed on said lower omnidirectional reflector and is opposite to said first semiconductor layer.

18. The light source unit of claim 16, wherein said first semiconductor layer has a portion extending outwardly of said light-generating layer and said second semiconductor layer, and an upper face that is exposed from said light-generating layer and said second semiconductor layer, said semiconductor structure further including a p-electrode that is formed on said second semiconductor layer, an n-electrode that is formed on said upper face of said first semiconductor layer, and side ominidirectional reflectors that are respectively formed on all except one of said lateral side faces, said upper omnidirectional reflector having a portion that is formed on said upper face of said first semiconductor layer.

19. The light source unit of claim 18, wherein each of said upper and lower omnidirectional reflectors and said side omnidirectional reflectors is a photonic crystal that includes periodically stacked units, each of which includes at least first and second dielectric layers that differ in dielectric constant.

20. The light source unit of claim 19, wherein said first dielectric layer is made from a material selected from the group consisting of TiO₂, Ta₂O₅, ZrO₂, ZnO, Nd₂O₃, Nb₂O₅, In₂O₃, SnO₂, Sb₂O₃, HfO₂, CeO₂, and ZnS, and said second dielectric layer is made from a material selected from the group consisting of SiO₂, Al₂O₃, MgO, La₂O₃, Yb₂O₃, Y₂O₃, Sc₂O₃, WO₃, LiF, NaF, MgF₂, CaF₂, SrF₂, BaF₂, AlF₃, LaF₃, NdF₃, YF₃, and CeF₃.
